(19) United States
(12) Patent Application Publication
(10) Pub. No.: US 2024/0072150 A1
(43) Pub. Date: Feb. 29, 2024

(54) MIS CONTACT STRUCTURE WITH METAL OXIDE CONDUCTOR

(71) Applicant: Acorn Semi, LLC, Palo Alto, CA (US)

(72) Inventors: Paul A. Clifton, Redwood City, CA (US); Andreas Goebel, Mountain View, CA (US)

(21) Appl. No.: 18/490,471

(22) Filed: Oct. 19, 2023

Related U.S. Application Data
(63) Continuation of application No. 17/094,651, filed on Nov. 10, 2020, now Pat. No. 11,843,040.
Application No. 17/094,651 is a continuation of application No. 16/742,098, filed on Jan. 14, 2020, now Pat. No. 10,872,964.
Application No. 16/742,098 is a continuation of application No. 16/175,637, filed on Oct. 30, 2018, now Pat. No. 10,553,695.
Application No. 16/175,637 is a continuation of application No. 15/451,164, filed on Mar. 6, 2017, now Pat. No. 10,147,798.
Application No. 15/451,164 is a continuation of application No. 15/186,378, filed on Jun. 17, 2016, now Pat. No. 9,620,611.

(51) Int. Cl. H01L 29/49; H01L 21/28; H01L 29/08; H01L 29/36; H01L 29/51; H01L 29/66; H04L 67/10; H04L 67/51

(52) U.S. Cl. CPC H01L 29/4966; H01L 21/28017; H01L 29/0895; H01L 29/36; H01L 29/517; H01L 29/66643; H04L 67/10; H04L 67/51

(57) ABSTRACT

An electrical contact structure (an MIS contact) includes one or more conductors (M-Layer), a semiconductor (S-Layer), and an interfacial dielectric layer (I-Layer) of less than 4 nm thickness disposed between and in contact with both the M-Layer and the S-Layer. The I-Layer is an oxide of a metal or a semiconductor. The conductor of the M-Layer that is adjacent to and in direct contact with the I-Layer is a metal oxide that is electrically conductive, chemically stable and unreactive at its interface with the I-Layer at temperatures up to 450° C. The electrical contact structure has a specific contact resistivity of less than or equal to approximately 10⁻⁵-10⁻⁷ Ω-cm² when the doping in the semiconductor adjacent the MIS contact is greater than approximately 2×10¹⁹ cm⁻³ and less than approximately 10⁻⁸ Ω-cm² when the doping in the semiconductor adjacent the MIS contact is greater than approximately 10²⁰ cm⁻³.

### RELATED APPLICATIONS

This is a CONTINUATION of U.S. application Ser. No. 17/094,651, filed 10 Nov. 2020, which is a CONTINUATION of U.S. application Ser. No. 16/742,098, filed 14 Jan. 2020, now U.S. Pat. No. 10,872,964, which is a CONTINUATION of U.S. application Ser. No. 16/175,637, filed 30 Oct. 2018, now U.S. Pat. No. 10,553,695, which is a CONTINUATION of U.S. application Ser. No. 15/451,164, filed 6 Mar. 2017, now U.S. Pat. No. 10,147,798, which is a CONTINUATION of U.S. application Ser. No. 15/186,378, filed 17 Jun. 2016, now U.S. Pat. No. 9,620,611, each of which is incorporated herein by reference.

### FIELD OF THE INVENTION

The present invention relates to what are generally known in the art as metal-insulator-semiconductor (MIS) electrical contacts, and in particular, such contacts in which the “insulator” is an interfacial dielectric layer that is an oxide of a metal, an oxide of a semiconductor, or both, and the “metal” is a conductive metal oxide.

### BACKGROUND

Metal-semiconductor contact resistivity is an important consideration in the fabrication of field effect transistors and becomes increasingly important as the dimensions of the contacts are scaled down and currently approach ten nanometers. MIS contacts are a relatively recent technological development, and may provide a contact resistivity that is lower than the resistivity of the equivalent direct metal-semiconductor contact between the same metal and semiconductor pair. As described in the Applicant's U.S. Pat. No. 7,084,423, incorporated herein by reference, a very thin, interfacial dielectric layer between the metal and semiconductor acts to reduce the Schottky barrier at the junction and at the same time has sufficient conductivity, despite being itself a dielectric with poor bulk electronic conduction, to provide a net improvement in the conductivity of the MIS junction.

### SUMMARY OF THE INVENTION

Described herein is an electrical contact structure including a conductor; a semiconductor (e.g., a group IV semiconductor such as silicon, germanium, or an alloy mixture of silicon, germanium, carbon, or tin; a group IV compound semiconductor such as SiC; a III-V compound semiconductor; a II-VI compound semiconductor; a two-dimensional semiconductor such as graphene, phosphorene; or a transition metal dichalcogenide such as monolayer molybdenum disulfide; or carbon nanotubes); and an interfacial dielectric layer of less than 4 nm thickness disposed between and in contact with both the conductor and the semiconductor, wherein the conductor is a conductive metal oxide, and wherein the interfacial dielectric layer is an oxide of a metal, an oxide of a semiconductor, or a mixture of both. Although the term “metal” is often used in the literature (as in “metal-insulator-semiconductor” contact), herein, we adopt the term “conductor” when referring to the conductive metal oxide in order to emphasize this nature of the contact element. In various embodiments, the electrical contact structure has a specific contact resistivity of less than or equal to approximately 10⁻⁵-10⁻⁷ Ω-cm² when the doping in the semiconductor adjacent the MIS contact is greater than approximately 2×10¹⁹ cm⁻³ and less than approximately 10⁻⁸ Ω-cm² when the doping in the semiconductor adjacent the MIS contact is greater than approximately 10²⁰ cm⁻³. In various embodiments the interfacial dielectric layer may be a material that is an insulator or a semiconductor in its bulk state. In some embodiments, the interfacial dielectric layer has a thickness in the range 0.2 nm to 4 nm, and may be one of: TiO₂, SrTiO₃, MgO, Al₂O₃, HfO₂, ZrO₂, Ta₂O₅, V₂O₅, BaZrO₃, La₂O₃, Y₂O₃, HfSiO₄, ZrSiO₄, CoO, NiO, ZnO, SiO₂. The conductive metal oxide layer may, in some embodiments, have a thickness in the range 0.5 nm to 3 nm and may be one of: (Nb,Sr)TiO₃, (Ba,Sr)TiO₃, SrRuO₃, MoO₂, OsO₂, WO₂, RhO₂, RuO₂, IrO₂, ReO₃, ReO₂, LaCuO₃, Ti₂O₃, TiO, V₂O₃, VO, Fe₃O₄, ZnO, InSnO or CrO₂. In some embodiments, the interfacial dielectric layer includes a separation layer (e.g., a further insulating oxide layer separating the conductor and the semiconductor). Preferably, the junction between the conductive metal oxide layer and the interfacial dielectric layer is chemically stable up to a temperature of 400° C. and more preferably, the junction between the conductive metal oxide layer and the interfacial dielectric layer is chemically stable up to a temperature of 450° C. For example, there is preferably no chemical reaction between the conductive metal oxide layer and the interfacial dielectric layer that substantially consumes the interfacial dielectric up to a temperature of 400° C. and more preferably no such chemical reaction up to a temperature of 450° C. Also, or alternatively, the contact resistivity of the device is preferably less than or equal to approximately 10⁻⁷ Ω-cm² after the device is heated to a temperature of 400° C. More preferably, the contact resistivity of the device remains less than or equal to approximately 10⁻⁷ Ω-cm² after the device is heated to a temperature of 450° C. In some embodiments, the conductive metal oxide layer of the electrical contact structure is contacted by a thin metal layer of a different metal, such as W, Ag, Al, Ta, Co, or Cr. Although examples of materials that may comprise the interfacial dielectric layer are specified herein, persons of ordinary skill in the art will appreciate that such materials may not have the precise stoichiometry of the examples. For instance, TiO₂ may more preferably be described as TiOₓ, with x less than or equal to 2 but greater than 1.5. Similar non-stoichiometric variants of the metal oxides described herein, together with mixed metal oxides and mixtures of metal and silicon or germanium oxides should be understood to be within the scope of the present invention. In some cases, non-stochiometric and also doped variants of the metal oxides exhibit semiconducting or even conducting properties, even if their undoped stoichiometric variants are considered dielectrics.

### BRIEF DESCRIPTION OF THE DRAWINGS

The present invention is illustrated by way of example, and not limitation, in the figures of the accompanying drawings, in which:

FIG. 1 illustrates an example of an MIS contact structure according to an embodiment of the present invention.

FIG. 2 illustrates a further example of an MIS contact structure according to an embodiment of the present invention.

FIGS. 3A, 3B, and 3C illustrate examples of structures created during fabrication of an MIS contact structure according to an embodiment of the present invention.

### DETAILED DESCRIPTION

As noted above, an MIS stack formed by a very thin, interfacial dielectric layer (termed herein an “I-Layer”) between a metal oxide conductor (or “M-Layer”) and a semiconductor (or “S-Layer”) (e.g., silicon, germanium, silicon carbide, or germanium tin) has sufficient conductivity, despite the dielectric itself having poor conductivity in its bulk state, to provide a net improvement in the conductivity (over that which would exist in the absence of the I-Layer) of the junction of which it is a constituent. To enable a favorable result with a lowering of the contact resistivity, it is necessary for the interfacial dielectric layer, which might normally be an insulating or semiconducting material in its bulk state, to be very thin—of the order of one nanometer—to enable a large current density to flow, for example by quantum mechanical tunneling.

For the specific purpose of forming improved contacts to n-type semiconducting materials, in which the current is carried by transport of electrons between the conductor and semiconductor, it may be preferred to use an interfacial dielectric layer that itself presents only a small energy barrier to electrons. An example of such a material is titanium dioxide, which is found to present only a very small barrier to electron flow between a metal and an n-type semiconductor, such as Si or Ge, of the order of zero to 0.15 electron volts. In general, with favorable band alignment, the dielectric metal-oxide thickness can be as much as 5 nm or even 10 nm.

Whilst MIS contacts with a titanium oxide interface layer have been demonstrated to be effective in reducing contact resistivity for a broad range of combinations of metals and semiconductors, a problem may arise when MIS contacts are integrated into the industrial manufacture of semiconductor devices in integrated circuits (“ICs”). Metal-semiconductor contacts are processed at what is known as the middle of line (MOL), which is the stage in integrated circuit manufacturing that occurs after transistor fabrication (front end of line, FEOL) and before the processing of metal interconnect layers (back end of line, BEOL). As a consequence the metal contacts are exposed to the processing temperatures or “thermal budget” of the processes that occur during the BEOL, including any annealing or sintering process steps that may be applied as part of the BEOL. In the current state of the art of semiconductor integrated circuit manufacturing, it is typical for the BEOL to involve exposure of the contacts to a temperature of around 400° C. over a period of approximately two hours. Such a thermal budget may cause serious degradation of the MIS contact properties, including returning the contact resistivity to a high level more consistent with a direct metal-semiconductor contact. The degradation is due most likely to a chemical reduction of the critical thin interface layer if it is an oxide (e.g., titanium oxide). Most metals have an affinity for oxygen, i.e., there is a chemical driving force to form a metal oxide when the metal is in the presence of oxygen, especially at elevated temperatures. As such, most metals when placed in contact with a metal oxide such as titanium dioxide (TiO₂) and heated will remove oxygen from the titanium dioxide, rapidly reducing the TiO₂ to a sub-stoichiometric titanium oxide and, upon continued heating thereafter, to what amounts to titanium metal with a high concentration of residual oxygen. We find experimentally, for example, that MIS contacts in which the metal is titanium, the interface layer is titanium oxide and the semiconductor is silicon rapidly degrade to titanium-silicon contacts when heated to 400° C. for as little as 30 seconds. The low Schottky barrier to n-type semiconductor and the corresponding low contact resistivity provided by the MIS structure is lost as a result of the thermal degradation of the interface layer.

We find therefore that there is a need to form an MIS contact structure of low contact resistivity that also has sufficient thermal stability to be useful in an IC manufacturing process. The present invention involves using a metal oxide as the conductive metallic layer (the M-Layer) in the MIS structure and using a different metal oxide or an oxide of a silicon or germanium as an I-Layer. The I-Layer generally comprises a material that would be an insulator or a semiconductor in its bulk state, and may include a separation layer (e.g., a further insulating layer separating the conductor and the semiconductor).

Although most metal oxides tend to be electrically insulating dielectrics, there are a number of metal oxides that exhibit electrically conductive or metallic properties. Examples of electrically conducting metal oxides (which may be suitable as conductive metal layers (M-Layers) in the present MIS structure) include but are not limited to (Nb,Sr)TiO₃, (Ba,Sr)TiO₃, SrRuO₃, MoO₂, OsO₂, WO₂, RhO₂, RuO₂, IrO₂, ReO₃, ReO₂, LaCuO₃, Ti₂O₃, TiO, V₂O₃, VO, NbO, Fe₃O₄, conducting ZnO, InSnO and CrO₂. Examples of insulating metal oxides that may be used as an I-Layer in the present MIS structure include but are not limited to TiO₂, MgO, Al₂O₃, HfO₂, ZrO₂, Ta₂O₅, V₂O₅, BaZrO₃, La₂O₃, Y₂O₃, HfSiO₄, ZrSiO₄, CoO, NiO, SrTiO₃ or (Ba,Sr)TiO₃, non-conducting ZnO, MnO, silicon oxide or germanium oxide. It may be noted that some metal oxides may exhibit a metal-insulator transition as a result of a change in temperature or pressure. For example the class of metal compounds known as Mott-Hubbard insulators, including the transition metal oxides NiO, Ti₂O₃, V₂O₃, Cr₂O₃, are insulating at low temperatures and conducting at high temperatures. Considering V₂O₃, this material makes an insulator-metal transition at a temperature of about 145 K at atmospheric pressure and makes an insulator-metal transition at a pressure of about 7 kilobar at “room temperature”, i.e., approximately 300 K. For the purposes of the present invention we are concerned with the electrical conductivity of metal oxides in the normal range of temperature and pressure experienced by MIS contacts during the normal operation of semiconductor integrated circuits—temperature typically in the range 0° C. to 125° C. and pressure close to atmospheric pressure. Non-stoichiometric variants of the metal oxides described herein, together with mixed metal oxides and mixtures of metal and silicon or germanium oxides should be understood to be within the scope of the present invention. In some cases, non-stochiometric and also doped variants of the metal oxides exhibit semiconducting or even conducting properties, even if their undoped stoichiometric variants are considered dielectrics.

The application of a metal oxide as a conducting or metallic layer is known in the art of metal-insulator-metal (MIM) capacitor fabrication—for example, in the manufacture of dynamic random access memory (DRAM) devices—wherein a charge storage capacitor is required to have a high specific capacitance and also to have sufficient thermal stability to survive BEOL processing. For example, U.S. Pat. No. 5,619,393, incorporated herein by reference, discloses a high-dielectric-constant material layer is formed between a lower thin unreactive film on a lower electrode base, and an upper thin unreactive film with an upper electrode then formed on the upper unreactive film. In the Technical Digest of the 1994 International Electron Devices Meeting, pp. 831-834, it is disclosed that a polycrystalline RuO₂ thin film is deposited by a reactive sputtering method on a TiN thin film serving as a diffusion barrier layer and the laminate of the TiN thin film and the polycrystalline RuO₂ thin film is subsequently patterned to define a composite RuO₂/TiN storage electrode before a SrTiO₃ thin dielectric film is deposited on the RuO₂/TiN. The SrTiO₃ thin dielectric film is selected for its good chemical and thermal stability and good insulating properties and the purpose of the paraelectric SrTiO₃ thin dielectric film is to provide the insulating dielectric layer for a DRAM capacitor. The insulating SrTiO₃ thin dielectric film is not thin enough to pass a current and is not in direct contact with a semiconductor.

Generally, the instant invention uses a thin, unreactive, and conductive film to contact the thin I-Layer material in an MIS contact structure. The thin, unreactive film may be a conductive oxide such as RuO₂ (others include: (Nb,Sr)TiO₃, (Ba,Sr)TiO₃, SrRuO₃, MoO₂, OsO₂, WO₂, RhO₂, IrO₂, ReO₃, ReO₂, LaCuO₃, Ti₂O₃, TiO, V₂O₃, VO, Fe₃O₄, ZnO, InSnO or CrO₂). In addition to highly conductive tungsten(IV) oxide, also known as tungsten dioxide, WO₂, there are other intermediate oxides of tungsten including W₁₈O₄₉, W₂₀O₅₈, and W₂₄O₇₀ that may for example be formed by reacting tungsten metal and tungsten trioxide.

The thin, unreactive film is generally less than 10 nm thick, preferably less than 5 nm thick, and most preferably between 0.5 nm and 3.0 nm thick. As used herein, the term “unreactive”, when used in reference to a material contacting an I-Layer material, means a material that provides a thermally stable conductive interface to the I-Layer material during and after processing (e.g., to temperatures in the range of approximately 350° C. or 450° C. in a forming gas or similar gas for on the order of approximately 2 hr.). Note that when a conductive metal oxide such as RuO₂ is used for the thin, unreactive, and conductive film, that layer can also contain some amount of unoxidized or partially oxidized metal, for example Ru. For example, a thin, unreactive film of RuO₂ which is chemically changed by becoming partially reduced during the deposition process of the complete metal stack and ensuing thermal cycles is still considered unreactive since it still provides a stable conductive interface to the I-Layer material. The I-Layer may be on the order of 0.2 nm-10 nm, or more preferably 0.2 nm-5 nm, or still more preferably, 0.2 nm-1.0 nm.

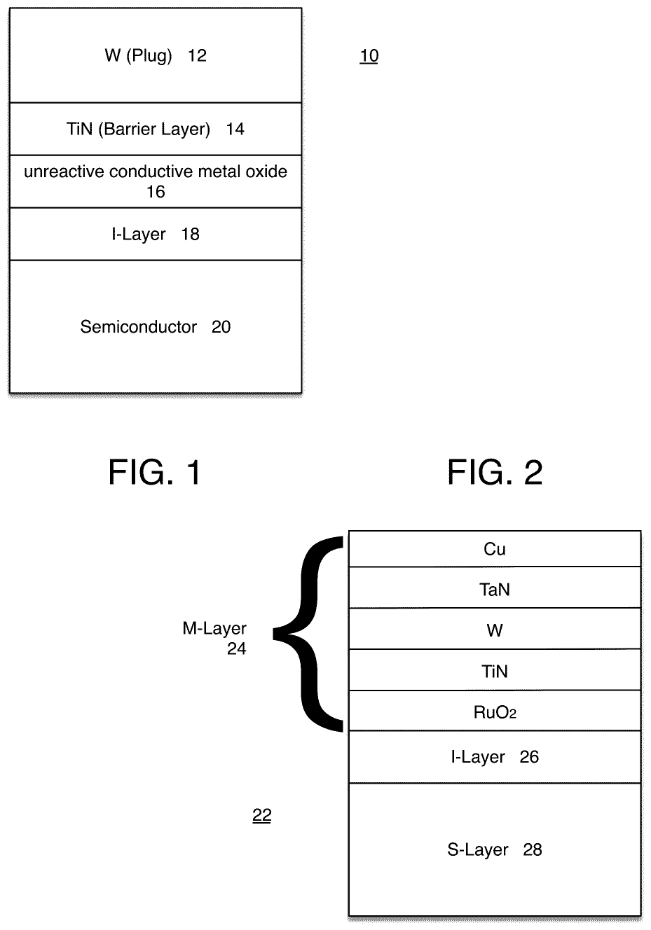

When the instant invention is applied to the fabrication of MIS contacts in integrated circuits, it is understood that several different metal layers constitute an interconnect system that is key to the operation of the integrated circuit. Typically, multiple highly conductive metal interconnect layers, often as many as ten or more, are used to form the complex interconnections between devices and these layers are most commonly copper surrounded (clad) by a barrier metal such as tantalum nitride (TaN). The multiple TaN-clad copper layers are separated by inter-layer dielectric (ILD) layers, with the ILD material being a reliable insulator such as silicon dioxide. The connection between the lowest copper interconnect layer and the MIS contact is typically by way of a tungsten plug formed in a contact via. To provide good adhesion of the W plug to the via, the via is typically first lined with a deposited thin layer of “adhesion” and/or “barrier” metal before the W is deposited. The adhesion or barrier metal is typically titanium nitride (TiN) or a Ti/TiN thin laminate. Referring to FIG. 1, the structure of an MIS contact 10 according to an embodiment of the instant invention thus includes, in sequence, a W plug 12 and a TiN barrier/adhesion layer 14, an unreactive, conductive metal oxide 16 (such as RuO₂), and an I-Layer 18 (such as TiO₂, TiSiₓO_{y}, or TiO₂/SiO₂), with the I-Layer 18 being in contact with the semiconductor 20. The semiconductor 20 is typically silicon, germanium, silicon germanium alloy, germanium tin alloy, or silicon germanium tin alloy but may also be a compound semiconductor such as SiC, GaN, InGaN, GaAs, InAs, InGaAs alloy, GaSb or InSb, terniary or quarterniary compound semiconductors, or a two-dimensional semiconductor such as graphene, silicene, germanene, phosphorene, monolayer molybdenum disulfide, or carbon nanotubes.

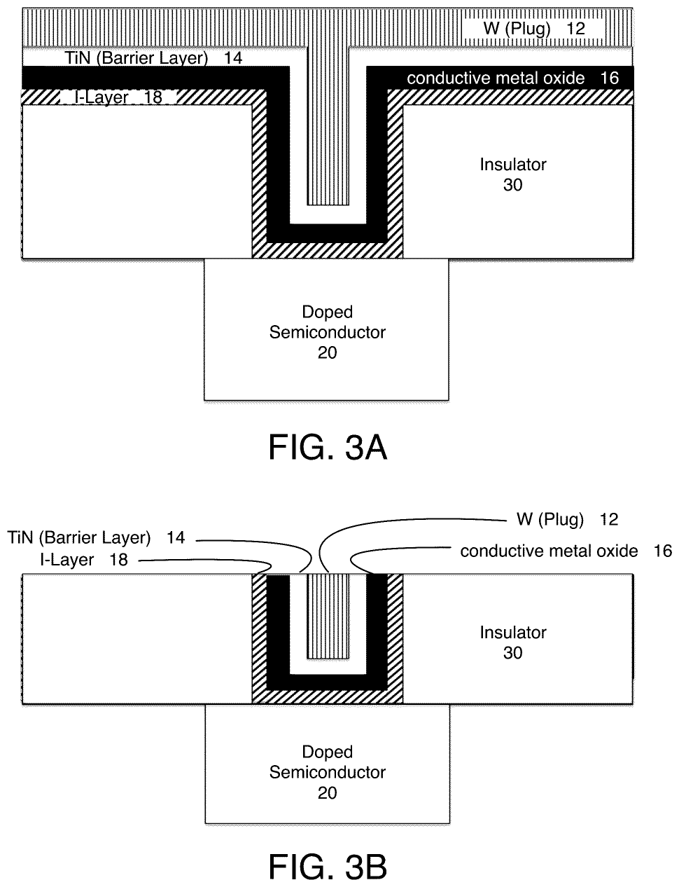

With reference to FIG. 2, the component parts of an MIS structure 22 according to an embodiment of the instant invention may therefore be described as follows: The M-Layer 24 is a stack of metals such as Cu/TaN/W/TiN/RuO₂. The I-Layer 26 comprises one or more oxides, an oxide of titanium TiOₓ and/or an oxide of silicon SiOₓ (such as TiO₂ or TiSiₓO_{y} or TiO₂/SiO₂), that would be considered insulator(s) or semiconductor(s) in bulk form but are conductive when made extremely thin. The S-Layer 28 is a semiconductor such as silicon or germanium or silicon germanium alloy. An innovative aspect of the invention is that the metal at the bottom of the metal stack i.e., the metal that is adjacent to and in direct contact with the I-Layer is a metal oxide that is electrically conductive, chemically stable, and unreactive at its interface with the I-Layer at temperatures up to 450° C. The disclosed MIS structure also has the property that the contact resistivity for the contact structure is lower than approximately 10⁻⁵-10⁻⁷ Ω·cm², and preferably lower than approximately 10⁻⁸ Ω·cm².

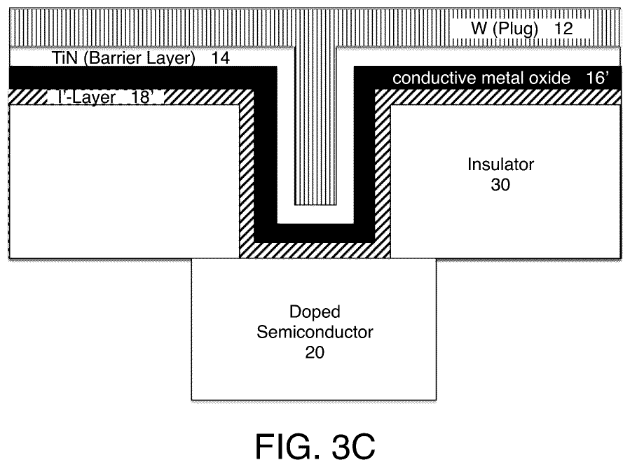

In one embodiment of the invention, illustrated in FIG. 3A, after forming a highly n-type doped region of semiconductor 20, which may for example be a source or drain region of a field effect transistor, the region is covered by a deposited layer of insulating material 30, which may be an oxide of silicon. Subsequently, a contact window, or via, is defined (e.g., by photolithographic or other means) and a hole is etched through the insulating layer to expose a surface of the n-type doped semiconductor region. The exposed surface of the n-type doped semiconductor region is cleaned, for example by a short exposure to hydrofluoric acid diluted in water, and then a first layer of a metal oxide (I-Layer, 18) is formed on the exposed surface. Thereafter a different metal oxide layer 16 that is electrically conductive is deposited over the first metal oxide layer 18. Subsequently, a layer of an adhesion or barrier metal 14 is deposited and the contact hole is then filled with a different bulk metal to form a metal plug 12. If any of the processes used to form the conductive material layers is not selective, those conductive material layers will be deposited on all surfaces including on top of the insulating material 30 as well as within the contact hole as illustrated in FIG. 3A. In such a case, those conductive material layers that are not deposited selectively within the contact hole are subsequently removed from atop the insulating layer, for example by chemical-mechanical polishing (CMP), leaving the conductive materials substantially filling the contact hole to form an MIS contact contained within the contact hole, as shown in FIG. 3B. Subsequently, multiple layers of metal interconnect separated by insulating material may be deposited and patterned and the whole assembly may be annealed at temperatures in excess of 300° C., and even at 400° C. or higher, to improve the functional properties or the reliability of the integrated circuit. Annealing may be in an atmosphere of hydrogen and nitrogen gas (so-called forming gas) or inert gas, and accumulated annealing time may be tens of minutes and as much as two hours.

In another embodiment of the invention, illustrated in FIG. 3C, after forming a highly n-type doped region of semiconductor 20, which may for example be a source or drain region of a field effect transistor, the region is covered by a deposited layer of insulating material 30, which may be an oxide of silicon. Subsequently, a contact window, or via, is defined (e.g., by photolithographic or other means) and a hole or trench is etched through the insulating layer to expose a surface of the n-type doped semiconductor region. The exposed surface of the n-type doped semiconductor region is cleaned, for example by a short exposure to hydrofluoric acid diluted in water, and then a first layer of a metal oxide (I′-Layer, 18′) is formed on the exposed surface. Thereafter a different metal oxide layer 16′ that is electrically conductive is deposited over the first metal oxide layer 18′. A layer of tungsten 14 is deposited by metalorganic chemical vapor deposition or atomic layer deposition and the contact hole is then filled with tungsten to form a tungsten plug 12. If any of the processes used to form the conductive material layers is not selective, those conductive material layers will be deposited on all surfaces including on top of the insulating material 30 as well as within the contact hole as illustrated in FIG. 3A. In such a case, those conductive material layers that are not deposited selectively within the contact hole are subsequently removed from atop the insulating layer, for example by chemical-mechanical polishing (CMP), leaving the conductive materials substantially filling the contact hole to form an MIS contact contained within the contact hole, as shown in FIG. 3B. Subsequently, multiple layers of metal interconnect separated by insulating material may be deposited and patterned and the whole assembly may be annealed at temperatures in excess of 300° C., and even at 400° C. or higher, to improve the functional properties or the reliability of the integrated circuit. Annealing may be in an atmosphere of hydrogen and nitrogen gas (so-called forming gas) or inert gas, and accumulated annealing time may be tens of minutes and as much as two hours.

In alternative embodiments, the process of forming the contact hole may expose more than one n-type doped region of semiconductor. The same process may expose at least one region of p-type doped semiconductor in addition to the at least one n-type doped region of semiconductor. The n-type doped region(s) of semiconductor may be silicon regions or silicon-carbon alloy regions or silicon-phosphorus alloy regions or other semiconductor regions. The p-type doped region(s) of semiconductor may be silicon regions or silicon-germanium alloy regions or germanium regions or other semiconductor regions.

In one embodiment of the invention, the n-type doped region of semiconductor is a silicon (Si) source or drain region of a field effect transistor, where the silicon is very heavily doped with phosphorus (P) to a concentration in excess of 10²⁰ cm⁻³ (which may be denoted as a silicon-phosphorus alloy, Si:P) the first metal oxide layer is titanium dioxide (TiO₂) and it is deposited by atomic layer deposition (ALD) to a thickness of between 0.2 nm and 3.0 nm, and the second metal oxide layer is conductive ruthenium oxide (RuO₂) deposited by ALD to a thickness of between 1.0 nm and 5.0 nm. The adhesion or barrier metal is titanium nitride (TiN), deposited by ALD to a thickness of between 1.0 nm and 5.0 nm, and the bulk metal that forms a metal plug is tungsten (W), deposited by chemical vapor deposition (CVD).

In another embodiment of the invention, the n-type doped region of semiconductor is a silicon (Si) source or drain region of a field effect transistor, where the silicon is very heavily doped with phosphorus (P), for example to a concentration in excess of 10²⁰ cm⁻³ (which may be denoted as a silicon-phosphorus alloy, Si:P) the first metal oxide layer (I-layer) is tungsten trioxide (WO₃) with a thickness of between 0.2 nm and 3.0 nm, and the second metal oxide layer (M-layer) is conductive tungsten oxide (e.g., WO₂ or a conductive tungsten oxide with stoichiometry between WO 2 and WO 3 such as W₁₈O₄₉) with a thickness of between 0.5 nm and 5.0 nm. The adhesion or barrier metal is tungsten (W), deposited by metalorganic chemical vapor deposition or atomic layer deposition to a thickness of between 0.5 nm and 5.0 nm, and the bulk metal that forms a metal plug is also tungsten (W), deposited by chemical vapor deposition (CVD) or physical vapor deposition (PVD). The first metal oxide (WO₃) is deposited by atomic layer deposition (ALD) or is formed by deposition of a thin layer of tungsten metal that is subsequently oxidized. The conductive tungsten oxide (e.g. W₁₈O₄₉ or WO₂) is deposited by ALD or CVD or is formed by reaction of tungsten metal with the WO₃ I-layer to form a conductive tungsten oxide layer on top of some remaining thickness of the WO₃ I-layer. The conductive tungsten oxide may have a composition intermediate between WO₂ and WO₃ (including one or a mixture of WO₂, W₁₈O₄₉, W₂₀O₅₈, W₂₄O₇₀) and the composition may vary in this range through the depth of the conductive tungsten oxide layer. Reaction of W with WO₃ forms a sub-stoichiometric tungsten oxide layer of composition ranging between WO₂ and WO₃ (including one or a mixture of WO₂, W₁₈O₄₉, W₂₀O₅₈, W₂₄O₇₀). Furthermore, one or a few atomic monolayers of silicon oxide may exist at the silicon interface between the WO₃ and the silicon. The metal that forms a metal plug may alternately be a low resistance metal, for example copper or silver.

In another embodiment of the invention, the n-type doped region of semiconductor is a silicon (Si) source or drain region of a field effect transistor, where the silicon is very heavily doped with a donor such as phosphorus (P), for example to a concentration in excess of 10²⁰ cm⁻³, the first metal oxide layer (I-layer) is V₂O₅ with a thickness of between 0.2 nm and 3.0 nm, and the second metal oxide layer (M-layer) is conductive vanadium oxide (e.g., V₂O₃) with a thickness of between 0.5 nm and 5.0 nm. The adhesion or barrier metal layer comprises tungsten (W) or vanadium (V) or a mixture of W and V, deposited by metalorganic chemical vapor deposition or atomic layer deposition to a thickness of between 0.5 nm and 5.0 nm. The first metal oxide (V₂O₅) is deposited by atomic layer deposition (ALD) or is formed by deposition of a thin layer of vanadium metal that is subsequently oxidized. The conductive vanadium oxide (e.g. V₂O₃) is deposited by ALD or CVD or is formed by reaction of vanadium metal with the V₂O₅ I-layer. The conductive vanadium oxide may have a composition intermediate between VO and VO₂ and the composition may vary in this range through the depth of the conductive vanadium oxide layer. Reaction of V from the adhesion or barrier metal layer with V₂O₅ forms a vanadium oxide layer of composition ranging between VO and VO₂ on top of some remaining thickness of the V₂O₅ I-layer. Furthermore, one or a few atomic monolayers of silicon oxide may exist at the silicon interface between the V₂O₅ and the silicon. The metal that forms a metal plug may alternately be a low resistance metal, for example copper or silver.

In another embodiment of the invention, the n-type doped region of semiconductor is a silicon (Si) source or drain region of a field effect transistor, where the silicon is very heavily doped with a donor such as phosphorus (P), for example to a concentration in excess of 10²⁰ cm⁻³, the first metal oxide layer (I-layer) is TiO₂ with a thickness of between 0.2 nm and 3.0 nm, and the second metal oxide layer (M-layer) is conductive tungsten oxide (e.g., WO₂) with a thickness of between 0.5 nm and 5.0 nm. The adhesion or barrier metal layer comprises tungsten (W), deposited by metalorganic chemical vapor deposition or atomic layer deposition to a thickness of between 0.5 nm and 5.0 nm. The first metal oxide (TiO₂) is deposited by atomic layer deposition (ALD) or is formed by deposition of a thin layer of titanium metal that is subsequently oxidized. The conductive tungsten oxide (e.g. WO₂) is deposited by ALD or CVD or is formed by reaction of tungsten metal from the adhesion or barrier metal layer with the TiO₂ I-layer. The conductive tungsten oxide may have a composition intermediate between WO₂ and WO_{2.95} and the composition may vary in this range through the depth of the conductive tungsten oxide layer. Reaction of W from the adhesion or barrier metal layer with TiO₂ forms a conductive mixed oxide layer comprising a mixture of tungsten and titanium oxides on top of some remaining thickness of the TiO₂ I-layer. Furthermore, one or a few atomic monolayers of silicon oxide may exist at the silicon interface between the TiO₂ and the silicon.

In other embodiments of the invention, the first metal oxide layer (I-Layer) may comprise any one of or a combination of WO₃, TiO₂, MgO, Al₂O₃, HfO₂, ZrO₂, Ta₂O₅, V₂O₅, BaZrO₃, La₂O₃, Y₂O₃, HfSiO₄, ZrSiO₄, CoO, NiO, GaO, SrTiO₃ or (Ba,Sr)TiO₃, silicon oxide or germanium oxide or doped or non-stochiometric insulating variants thereof. Moreover the first metal oxide may alternatively be deposited by atomic layer deposition (ALD), plasma-enhanced ALD, chemical vapor deposition (CVD), plasma-enhanced CVD, atomic vapor deposition, oxidation of a deposited thin film of the metal, laser ablation, physical vapor deposition, or by reaction of a metal with a thin layer of an oxide of the n-type doped region of semiconductor. The first metal oxide may be a mixed oxide, comprising the oxides of two different metals (such as hafnium zirconium oxide, HfₓZr₁₋ₓO₂) or comprising the oxides of a metal and a semiconductor such as silicon or germanium, such as titanium silicate, TiSiₓO_{y} or a mixed metal/semiconductor oxide with some amount of nitrogen (i.e. a metal silicon oxynitride such as titanium silicon oxynitride).

In still further embodiments of the invention, the second metal oxide that is electrically conductive (M-layer) may comprise any one of or a combination of SrRuO₃, a conductive oxide of tungsten (e.g., WO₂, W₂O₅, or a mixture of tungsten oxides with compositions ranging between WO₂ and WO_{2.95} including one or a mixture of WO₂, W₁₈O₄₉, W₂₀O₅₈, W₂₄O₇₀, W₂₅O₇₃, W₄₀O₁₁₈), LaCuO₃, Fe₃O₄, LaSrCoO₃, conducting ZnO, and CrO₂, or an oxide of ruthenium (RuOx) or iridium (IrOx), a dioxide of ruthenium (RuO₂), rhodium (RhO₂), palladium, osmium (OsO₂), or iridium (IrO₂), or a conductive oxide of rhenium (ReO₂ or ReO₃), titanium (Ti₂O₃ or TiO) or vanadium (V₂O₃ or VO) or indium tin oxide (ITO) or aluminum-doped zinc-oxide (AZO) or doped or non-stochiometric conducting variants thereof. The second metal oxide may alternatively be deposited by reactive sputtering (of the metal in a plasma comprising oxygen), ALD, CVD, laser ablation, cyclic voltametric deposition, anodic deposition, electrophoretic deposition, oxidation of a thin film of the metal, or any of the other means discussed above.

As noted above, although examples of metal oxides that may comprise the interface layer are specified herein, persons of ordinary skill in the art will appreciate that such metal oxides may not have the precise stoichiometry of the examples. For instance, TiO2 may more preferably be described as TiOx, with x less than or equal to 2 but greater than 1.5. Similar stoichiometries of others of the metal oxides described herein should be understood to be within the scope of the present invention. Furthermore persons of ordinary skill in the art will appreciate that such metal oxides may include some amount of nitrogen, the amount of nitrogen being less than the amount of oxygen.

In other embodiments the adhesion or barrier metal may be tantalum nitride or ruthenium oxide or tungsten or CoWP. The adhesion or barrier metal may be deposited by atomic layer deposition or chemical vapor deposition (CVD) or metal organic chemical vapor deposition (MOCVD) or physical vapor deposition (PVD). The bulk metal that forms a metal plug may be cobalt or copper or aluminum or silver or a plurality of carbon nanotubes. The metal that forms a metal plug may alternatively be deposited by CVD, PVD, sputtering or electrochemical deposition.

A similar process may be applied to form MIS contacts to p-type doped regions of semiconductor material.

In various embodiments, the layers described herein may be deposited in a single process chamber (in sequential processing steps), in different chambers of a multi-chamber processing tool, or in separate processing tools.

Thus, described herein is an electrical contact structure including a conductor; a semiconductor (e.g., a III-V compound semiconductors or a semiconductor comprising one or several of the group IV elements silicon, germanium, carbon, or tin); and an interfacial dielectric layer of less than 4 nm thickness disposed between and in contact with both the conductor and the semiconductor, wherein the conductor is a conductive metal oxide, and wherein the interfacial dielectric layer is an oxide of a metal or an oxide of a semiconductor or an oxide of multiple different metals or metal(s) and semiconductor(s). In various embodiments, the electrical contact structure has a specific contact resistivity of less than or equal to approximately 10⁻⁵-10⁻⁷ Ω-cm² when the doping in the semiconductor adjacent the MIS contact is greater than approximately 2×10¹⁹ cm⁻³ and less than approximately 1×10⁻⁸ Ω-cm² when the doping in the semiconductor adjacent the MIS contact is greater than approximately 10²⁰ cm⁻³. Alternatively, or in addition, the interface layer is a material that would be an insulator or a wide band gap semiconductor in its bulk state. In some embodiments, the interfacial dielectric layer has a thickness in the range 0.2 nm to 10 nm, preferably 0.2 nm to 4 nm, and may be one of: WO₃, TiO₂, MgO, Al₂O₃, HfO₂, ZrO₂, Ta₂O₅, V₂₀₅, BaZrO₃, La₂O₃, Y₂O₃, HfSiO₄, ZrSiO₄, CoO, NiO, GaO, SrTiO₃ or (Ba,Sr)TiO₃, silicon oxide or germanium oxide. The conductive metal oxide layer may have a thickness in the range 0.5 nm to 3 nm (although in other embodiments different thicknesses may be used) and may be one of: WO₂ (or a mixture of tungsten oxides with compositions ranging between WO₂ and WO_{2.95} including one or a mixture of WO₂, W₁₈O₄₉, W₂₀O₅₈, W₂₄O₇₀, W₂₅O₇₃, W₄₀O₁₁₈), (Nb,Sr)TiO₃, (Ba,Sr)TiO₃, SrRuO₃, MoO₂, OsO₂, WO₂, RhO₂, RuO₂, IrO₂, ReO₃, ReO₂, LaCuO₃, Ti₂O₃, TiO, V₂O₃, VO, Fe₃O₄, zinc oxide (ZnO), indium tin oxide (ITO), aluminum-doped zinc-oxide (AZO), InSnO or CrO₂. In some embodiments, the interfacial dielectric layer includes a separation layer (e.g., a further insulating oxide layer separating the conductor and the semiconductor). Preferably, the junction between the conductive metal oxide layer and the interfacial dielectric layer is chemically stable up to a temperature of 400° C. and more preferably chemically stable up to a temperature of 450° C. For example, there is preferably no chemical reaction between the conductive metal oxide layer and the interfacial dielectric layer that substantially consumes the interfacial dielectric up to a temperature of 450° C. Also, or alternatively, the contact resistivity of the device is preferably less than or equal to approximately 10⁻⁷ Ω-cm² after the device is heated to a temperature of 400° C. More preferably, the contact resistivity of the device remains less than or equal to approximately 10⁻⁷ Ω-cm² after the device is heated to a temperature of 450° C. In some embodiments, the conductive metal oxide layer of the electrical contact structure is contacted by a thin metal layer of a different metal.

What is claimed is:

1. A metal-insulator-semiconductor electrical contact, comprising a first conductor that includes a metal oxide that is electrically conductive; a semiconductor layer; and an interfacial dielectric layer of 0.2 nm to 10 nm thickness disposed between and in contact with both the first conductor and the semiconductor layer, the interfacial dielectric layer comprising at least a layer of a metal silicate or a non-stochiometric variant thereof.

2. The metal-insulator-semiconductor electrical contact of claim 1, wherein the metal silicate is hafnium silicate, zirconium silicate, or titanium silicate, or a mixture thereof.

3. The metal-insulator-semiconductor electrical contact of claim 1, wherein the metal silicate is hafnium silicate, zirconium silicate, or titanium silicate, or a non-stoichiometric variant thereof.

4. The metal-insulator-semiconductor electrical contact of claim 1, wherein the interfacial dielectric layer further includes an oxide of silicon or an oxide of germanium.

5. The metal-insulator-semiconductor electrical contact of claim 1, wherein the first conductor is in direct contact with the interfacial dielectric layer and is a metal oxide that, in addition to being electrically conductive, is chemically stable and unreactive at its interface with the interfacial dielectric layer at temperatures up to 450° C.

6. The metal-insulator-semiconductor electrical contact of claim 1, wherein a stack of metals is in contact with the first conductor.

7. The metal-insulator-semiconductor electrical contact of claim 6, wherein the stack of metals includes a layer of W, Ag, Al, Ta, Co, or Cr in contact with the first conductor.

8. The metal-insulator-semiconductor electrical contact of claim 6, wherein the stack of metals includes a layer of titanium nitride in contact with the first conductor.

9. The metal-insulator-semiconductor electrical contact of claim 1, wherein a semiconductor of the semiconductor layer is doped n-type.

10. The metal-insulator-semiconductor electrical contact of claim 1, wherein the semiconductor layer forms at least a part of a source or drain in a field effect transistor.

11. The metal-insulator-semiconductor electrical contact of claim 1, wherein the electrical contact has a specific contact resistivity of less than or equal to approximately 10⁻⁵-10⁻⁷ Ohm-cm when doping in a semiconductor adjacent the metal-insulator-semiconductor electrical contact is greater than approximately 2×10¹⁹ cm⁻³, and less than approximately 10⁻⁸ Ohm-cm when the doping in the semiconductor adjacent the metal-insulator-semiconductor electrical contact is greater than approximately 10²⁰ cm⁻³.

12. The metal-insulator-semiconductor electrical contact of claim 1, wherein the electrical contact has a specific contact resistivity of less than or equal to approximately 10⁻⁷ Ohm-cm after the metal-insulator-semiconductor electrical contact is heated to a temperature of 400° C.

13. The metal-insulator-semiconductor electrical contact of claim 1, wherein the electrical contact has a specific contact resistivity of less than or equal to approximately 10⁻⁷ Ohm-cm after the metal-insulator-semiconductor electrical contact is heated to a temperature of 450° C.

14. The metal-insulator-semiconductor electrical contact of claim 1, wherein the interfacial dielectric layer is between 0.2 nm and 4 nm thick.

15. The metal-insulator-semiconductor electrical contact of claim 14, wherein the metal silicate is hafnium silicate, zirconium silicate, or titanium silicate, or a non-stoichiometric variant thereof.

16. The metal-insulator-semiconductor electrical contact of claim 15, wherein the first conductor is formed as a layer that is 0.5 nm-3.0 nm thick.

17. The metal-insulator-semiconductor electrical contact of claim 16, wherein the first conductor is one of: (Nb,Sr)TiO₃, (Ba,Sr)TiO₃, SrRuO₃, MoO₂, OsO₂, WO₂, RhO₂, RuO₂, IrO₂, ReO₃, ReO₂, LaCuO₃, Ti₂O₃, TiO, V₂O₃, VO, Fe₃O₄, ZnO, InSnO or CrO₂.

18. The metal-insulator-semiconductor electrical contact of claim 1, wherein the interfacial dielectric layer includes a separation layer.

19. The metal-insulator-semiconductor electrical contact of claim 1, wherein the semiconductor layer is one of: Si; Ge; an alloy of Si and Ge; an alloy of Ge and Sn; an alloy of Ge, Sn, and Si; SiC; GaN; InGaN; GaAs; InAs; InGaAs alloy; GaSb; InSb; terniary or quarterniary compound semiconductors, graphene, silicene, germanene, phosphorene, monolayer molybdenum disulfide, or carbon nanotubes.

20. The metal-insulator-semiconductor electrical contact of claim 1, wherein the first conductor is contacted by a thin metal layer of a metal different than that of the first conductor.
